(19) United States
(12) Patent Application Publication
(10) Pub. No.: US 2008/0068625 A1
(43) Pub. Date: Mar. 20, 2008

(54) Image control system and method incorporating a graininess correction

(75) Inventors: Yee S. Ng, Fairport, NY (US); Chung-Hui Kuo, Fairport, NY (US); Di Lai, Rochester, NY (US)

Correspondence Address: Mark G. Bocchetti;Patent Legal Staff, Eastman Kodak Company, 343 State Street, Rochester, NY, 14650-2201, US

(73) Assignee: Eastman Kodak Company

(21) Appl. No.: 11/521,990

(22) Filed: Sep. 15, 2006

(51) Int. Cl. G03F 3/08

(52) U.S. Cl. 358/1.9; 358/518

(57) ABSTRACT

A color image control system and method are provided for improving the image control of printing systems, including digital front-end processors, color printers and post-finishing system. This color image control system incorporate a graininess correction including measurement and calibration using measurements of a graininess magnitude.

### FIELD OF THE INVENTION

The invention relates generally to the field of printing, and more particularly to processes and apparatus for enhancing color in digital color reproduction systems that incorporate a graininess correction.

### BACKGROUND OF THE INVENTION

Digital color reproduction printing systems typically include digital front-end processors, digital color printers, and post finishing systems (e.g., UV coating system, glosser system, laminator system, etc). These systems reproduce original color onto substrates (such as paper). The digital front-end processes take input electronic files (such as PDF or postscript files) composed of imaging commands and/or images from other input devices (e.g., a scanner, a digital camera) together with their own internal other function processes (e.g., raster image processor, image positioning processor, image manipulation processor, color processor, image storage processor, substrate processor, etc) to rasterize the input electronic files into proper image bitmaps for the printer to print. An operator may be assisted to set up parameters such as layout, font, color, paper, post-finishing, and etc among those digital font-end processes. The printer (e.g., an electrographic printer) takes the rasterized bitmap and renders the bitmap into a form that can control the printing process from the exposure device to writing the image onto paper. The post-finishing system finalizes the prints by adding finishing touches such as protection, glossing, and binding etc.

In an electrophotographic modular printing machine of known type, for example, the Eastman Kodak NexPress 2100 printer manufactured by Eastman Kodak, Inc., of Rochester, N.Y., color toner images are made sequentially in a plurality of color imaging modules arranged in tandem, and the toner images are successively electrostatically transferred to a receiver member adhered to a transport web moving through the modules. Commercial machines of this type typically employ intermediate transfer members in the respective modules for the transfer to the receiver member of individual color separation toner images. In other printers, each color separation toner image is directly transferred to a receiver member.

Electrophotographic printers having multicolor capability are known to also provide an additional toner depositing assembly for depositing clear toner. The provision of a clear toner overcoat to a color print is desirable for providing protection of the print from fingerprints and reducing certain visual artifacts. However, a clear toner overcoat will add cost and may reduce the color gamut of the print; thus, it is desirable to provide for operator/user selection to determine whether or not a clear toner overcoat will be applied to the entire print. In U.S. Pat. No. 5,234,783, issued on Aug. 10, 1993, in the name of Yee S. Ng, it is noted that in lieu of providing a uniform layer of clear toner, a layer that varies inversely in thickness according to heights of the toner stacks may be used instead as a compromise approach to establishing even toner stack heights. As is known, the respective color toners are deposited one upon the other at respective locations on the receiver member and the height of a respective color toner stack is the sum of the toner contributions of each respective color and so the layer of clear toner provides the print with a more even or uniform gloss.

In U.S. patent application Ser. No. 11/062,972, filed on Feb. 22, 2005, in the names of Yee S. Ng et al., a method is disclosed of forming a print having a multicolor image supported on a receiver member wherein a multicolor toner image is formed on the receiver member by toners of at least three different colors of toner pigments which form various combinations of color at different pixel locations on the receiver member to form the multicolor toner image thereon; forming a clear toner overcoat upon the multicolor toner image, the clear toner overcoat being deposited as an inverse mask; pre-fusing the multicolor toner image and clear toner overcoat to the receiver member to at least tack the toners forming the multicolor toner image and the clear toner overcoat; and subjecting the clear toner overcoat and the multicolor toner image to heat and pressure using a belt fuser to provide an improved color gamut and gloss to the image. The inverse masks, the pre-fusing conditions, and the belt fuser set points can be optimized based on receiver member types to maximize the color gamut. However, due to the many variables that occur before, during and after printing, there is a need for a better, more efficient and cost effective way to correct for color inaccuracies.

Color inaccuracies, including graininess, occur in all printing systems, including the electrophotographic printing systems. The system environment can change when components, such as the fuser roller, change their operational characteristics over time. Typically linearization processes are used to re-calibrate the printer system, in conjunction with the use of other devices, so that the digital front-end processors are more independent from printer behavior changes. However, in the whole color reproduction printing system, which includes both printer and post finishing system (e.g., UV coater, glosser, and etc), the linearization process alone cannot fully correct the whole color reproduction system variability with out effective controls and controlling systems, such as effective macroscopic color measurement devices and color measurement systems. Without these controlling systems the resultant colors may be incorrectly shifted (for example, red shift or green shift), and the resulting reproduction may be perceived as unacceptable to the customer. It is important to make corrections and adjustments to recreate the desired perceived colors. However, this can be time consuming and expensive using the current control systems, as well as ineffective.

The use of scanners, such as flatbed scanners alone has not been successful as a macroscopic color-measuring device since scanners have very different color response characteristics which limits the utility of a flatbed scanner as a macroscopic color measuring device. For example flatbed scanners first project the entire spectrum of reflected light onto three sensors with long, medium and short wavelength light absorption peaks, denoted as {Red}, {Green}, and {Blue} sensors.

Scanners, such as flatbed scanners, are not manufactured to a standard color response characteristic and the response characteristics of individual scanners are very different from standard human visual response characteristics and often differ substantially between different models. These features severely limit the utility of a flatbed scanner as a macroscopic color-measuring device. Consequently, the calculated metamerism between the device {RGB} color response characteristics and the CIE standardized human visual response characteristics provides a lower bound on color measurement error in color measurements using flatbed scanners.

The present invention overcomes this shortcoming by making image control, including color measurement and control that incorporates a graininess correction, more efficient and accurate and allowing it to occur automatically during the printing run. The following invention solves the current problems with color image control in a wide variety of situations.

### SUMMARY OF THE INVENTION

In accordance with an object of the invention, both a system and a method are provided for improving the image control of printing systems, and specifically the efficiency and accuracy of color image control that incorporate a graininess correction. More specifically, the invention relates to an automatic image control, including measurement and calibration, by identifying one or more ROI (region of interest), determining a current graininess value, such as graininess magnitude for each selected color component in the ROI of a digital printing system, and calculating a graininess difference between the current graininess magnitude and a nominal expected graininess value to determine when the calculated graininess difference falls outside an expected or tolerable range; and taking appropriate corrective action.

### BRIEF DESCRIPTION OF THE DRAWINGS

FIG. 1 is a schematic illustration of a printer system according to the present invention for use in conjunction with a image control system and method.

FIG. 2 illustrates the image control system according to the present invention for use in conjunction with a print engine or printer apparatus.

FIG. 3 is a schematic illustration of a calibration according to the present invention.

FIG. 4 is an illustration of a granularity representation according to the present invention.

FIG. 5 shows a graininess map.

FIG. 6 shows another portion of the present invention.

FIG. 7 is another illustration of a graininess map.

FIG. 8 shows visual graininess versus % coverage.

FIG. 9 further shows the present invention.

FIG. 10 further shows the present invention.

FIG. 11 further shows the present invention.

FIG. 12 further shows the present invention.

FIG. 13 further shows the present invention.

FIG. 14 further shows the present invention.

FIG. 15 further shows the present invention.

FIG. 16 is a flow chart illustration of the process steps according to one embodiment of the invention.

FIG. 17 is a flow chart illustration of the process steps according to one embodiment of the invention.

FIG. 18 is a flow chart illustration of the process steps according to one embodiment of the invention.

FIG. 19 is a flow chart illustration of the process steps according to one embodiment of the invention.

### DETAILED DESCRIPTION OF THE INVENTION

The present description will be directed in particular to elements forming part of, or cooperating more directly with, apparatus and methods in accordance with the present invention. It is to be understood that elements not specifically shown or described may take various forms well known to those skilled in the art.

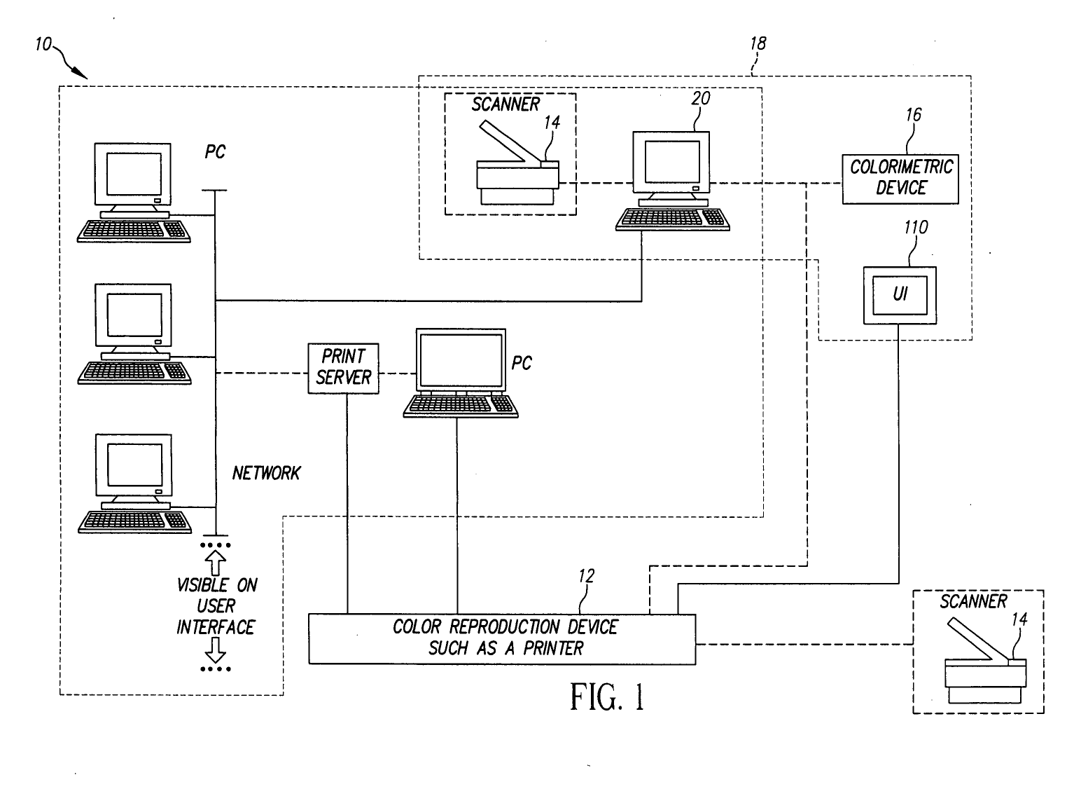

FIG. 1 shows schematically a printing system 10, including an electrophotographic printer or other printing devices 12, sometimes referred to as simply printers but not limited to the traditional printer but also including plate production devices, and copiers that can print on a receiver, such as paper, metal, press sheets, cloth, ceramics and substrates that are printable. Also shown is an image capturing device 14, such as a scanner and or camera or other device with scanning capability and a colorimetric measurement device 16, and related devices and sensors that make up a image control system 18 that will be discussed below in more detail. Electrophotographic printers are well known in the art, and are preferred in many applications; alternatively, other known types of printing systems may be used. Plural writer interfaces and development stations may be provided for developing images in plural colors, or from marking particles of different physical characteristics. Full process color electrophotographic printing is accomplished by utilizing this process for each of four, five or more marking particle colors (e.g., black, cyan, magenta, yellow, and clear).

The image control system 18 includes a controller or logic and control unit (LCU) 20, preferably a digital computer or microprocessor operating according to a stored program for sequentially actuating the workstations within printer system 10, effecting overall control of printer 12 and its various subsystems, including the image capturing device 14, such as a scanner and or camera or other device with scanning capability and a colorimetric measurement device 16, and related devices and sensors. These plus other possible components and software make up the image control system 18, which can be described as a serial combination of digital workflow process and one or more color reproduction devices, such as various physical printing processes. The Logic and Control Unit (LCU) 20 including one or more computers acting in response to signals from various sensors associated with the apparatus provides timing and control signals to the respective components to control the various components and process control parameters of the apparatus in accordance with methods well known by those skilled in the art. The image control system 18 includes the controller or logic and control unit (LCU) 20, preferably a digital computer or microprocessor operating according to a stored program for sequentially actuating the workstations within printer 12, effecting overall control of printer 10 and its various subsystems. Aspects of process control are described in U.S. Pat. No. 6,121,986 incorporated herein by this reference.

The LCU 20 includes a microprocessor and suitable tables and control software which is executable by the LCU 20. The control software is preferably stored in memory associated with the LCU 20. Sensors associated with the fusing and glossing assemblies, as well as other image quality features, provide appropriate signals to the LCU 20. In any event, the glosser and other image control elements can also have separate controls providing control over items such as the temperature of the glossing roller and the downstream cooling of the fusing belt and control of glossing nip pressure. In response to one or more sensors, the LCU 20 issues command and control signals that adjust all aspects of the image that determine image quality, such as the heat and/or pressure within fusing nip (not shown) so as to reduce image artifacts which are attributable to and/or are the result of release fluid disposed upon and/or impregnating a receiver member that is subsequently processed by/through a finishing device such as a glossing assembly (not shown). Additional elements provided for control may be assembled about the various module elements, such as for example a meter for measuring the uniform electrostatic charge and a meter for measuring the post-exposure color within a patch area of an image area on the printed surface.

The color printing device and system needs to be calibrated and characterized for accurate color reproduction that incorporate a graininess correction. This includes setting the printer to a standard specification for each color separation as well as printing and measuring large numbers of test patches to construct an accurate color transformation. The color transformation that characterizes the printing system maps color, bi-directionally, between device-dependent color (used in printing a document) and device-independent color (e.g. in the document to be printed). For example, it transforms the device independent CIELAB color system data, defined above, into CMYK data. The color transforms may be stored in a look-up table (LUT) format, in general, for easy access in processing color data. The International Color Consortium (ICC) color profile, which characterizes the printing system, contains multiple color transformation tables in LUT form.

Corrections can be made for graininess, which is a subjective response, as well as for granularity, which is an objective measurement. One way to correct for granularity (an objective measurement) is by using a fixed look up table (LUT) with or without a graininess conversion, such as described below. One difference between these measurements and related corrections is that granularity does not put an importance (visual weighting function) on the visual sensitivity to grain based on color, but graininess does. When only monitoring a few fixed color which are already pre-weighted, then granularity measurement may be sufficient from a monitoring and control viewpoint. In addition it is possible to use granularity tracking and corrective action in conjunction with the use of ROI and accumulation discussed below to take corrective action. This is valuable especially if somebody does not plan to go across colors. For example when only monitoring cyan, magenta, yellow etc on process control patches, then granularity measurement will do. Even for specific color such as a certain skin tone. Graininess is useful when we go across in diagnostic, such as yellow is less important than magenta, for example, so when it comes to corrective action, the problem has to be a lot bigger in yellow granularity before the fix needs to be done compared to magenta granularity. Graininess values even the field, hence corrective action is taken if a certain visual grain is above a threshold. Granularity will need different thresholds for different colors. For more complicated image content, graininess metric is easier to use. However, if only a few colors need to be tracked, granularity metric can be used effectively. Of course, a limited set of threshold values can also be used for graininess values measurement and control (for example, personal preference of one color over the others, etc.).

The LCU 20 also is programmed to provide closed-loop control of printer machine 10 in response to signals from various sensors and encoders. Aspects of process control are described in U.S. Pat. No. 6,121,986 incorporated herein by this reference. The printing device prints one or more images in one or more colors, including black and clear. The image may be included in a set of one or more images, such as in images of the pages of a document. An image may be divided into segments, objects, or structures each of which is in itself an image. A segment, object or structure of an image may be of any size up to and including the whole image.

The LCU 20 will typically include temporary data storage memory, a central processing unit, timing and cycle control unit, and stored program control. Data input and output is performed sequentially through or under program control. Input data can be applied through input signal buffers to an input data processor, or through an interrupt signal processor, and include input signals from various switches, sensors, and analog-to-digital converters internal to printing system 10, or received from sources external to printing system 10, such from as a human user or a network control. The output data and control signals from LCU 20 are applied directly or through storage latches to suitable output drivers and in turn to the appropriate subsystems within printing system 10. The look-up table based on a complete color representation in the relevant color dimension from three color dimensions, e.g. {L*,a*,b*}, in the CIELAB color space. This can include a nominal graininess value for each color that provides a nominal expected graininess value and/or granularity for that printer, paper, color, screen and other distinguishable criteria that affect the output, including the quality of the print. Other methods could be used and include graphical or mathematical representations of the corrective measures and could also include graphical or mathematical representations of the nominal values in a like way.

Before color control and calibration was supplied using accurate macroscopic color measurement and relied on the use of a colorimetric measurement device 16, such as a colorimeter or a spectrophotometer, to provide a surrogate for human visual response. The colorimetric measurement using a spectrophotometer first estimates the entire spectral response of the reflected light, and then, using standardized response characteristics, converts the spectral response to provide measurements according to color standards, such as {CIE XYZ, {CIELab} and {Reflection Densities} and achieves highly accurate color estimation with small between-instrument and inter-instrument variations.

The traditional scanner calibration utilizes a test target, printed with a fixed set of colorants that samples the entire printer device color space, for example CMYK or RGB. A scan of this well-defined test target provides a representation of the target in Scanner RGB values. A colorimetric measurement device, such as spectrophotometer, is also utilized to provide colorimetric measurements of this same printed test target. A multidimensional color mapping function from the scanner device color space, Scanner RGB, to the colorimetric color space, such as CIELAB, can then be created. Because the scanner is not a colorimetric measurement device, the color mapping function has to be re-created when one or more colorants are changed. Moreover, it is well known that this straightforward approach is not accurate enough for applications demanding high color stability and accuracy.

The image control system 18, including an image capture system adapted to capture a digital image of the receiver after an image has been printed, and to generate captured image data reflecting the appearance of the image on the receiver is shown in FIG. 1. In the image control system 18, the image capturing device 14, for example a flat bed scanner, is used to estimate the macroscopic color variation in print samples by capturing values. When the image capturing device captures the reproduced document to produce a scanned document it will register the captured reproduced document with the extracted virtual device document in such a way that that the ROI values can be determined in a predetermined or automatic manner so that the image capturing device measure the captured color values. When this is done in combination with the printer 12, the image-capturing device 14 can automatically monitor the color variation across a series of print samples without human intervention, which significantly reduces the cost of tracking printing process variations. This overcomes the shortcomings of previous printing systems by adjusting the calibration system in such a way that the metamerism induced color error is significantly reduced so that the objective of quantifying the color variations within a printed page or between pages can be achieved.

The image capturing device 14, here shown as the color scanner in the image control system 18, is different from the colorimetric measurement device 16 because of differences in the sensor spectral responsitivities from the responsivities of the CIE standard observer. Thus, observer color metamerism imposes a lower boundary on the measurement error when the image capturing device 14 is used to replace the macroscopic colorimetric measurement device as is done in the image control system 18 and the related method. The image control device is able to benefit from the attributes that the image capturing device 14 has, such as its capability of capturing large areas in fine detail allowing a scanner to quantify microscopic image artifacts and its convenience, efficiency and lower cost. The image control system 18 is able to replace the macroscopic colorimetric measurement device with the image capturing device 14 in the image control system 18 by allowing only one colorant to be present in a test target at a time. As a result, only one-dimensional color information is available to describe the color appearing on the page in a restricted manner.

Reflection densities are a natural choice in this controlled and highly restricted environment. However this constraint cannot be utilized when using the flatbed scanner to measure color with at least two colorants present. A complete color representation requires all three color dimensions, e.g. {L*,a*,b*}, in the CIELAB color space. To reach a compromise between a method, including an algorithm, applicability and transformation accuracy, assume that the printing workflow is transparent to all users. Although this assumption is rather restrictive, for example, when we are asked to evaluate image quality attributes objectively on any given printed target, the printing workflow is usually under control when a set of test targets is sent to a printing system for quality assessment and process diagnosis. As a result, it is reasonable to assume that this prior information with respect to the current printing workflow can be propagated to the following scanning process so as to facilitate the scanner calibration.

Basic subtractive color principles indicates that {cyan, magenta, yellow} can be considered as the complement colors of {red, green, blue} in terms of their spectral responsitivities. Assuming that a flatbed scanner with {Red}, {Green} and {Blue} sensors can reliably quantify the {cyan, magenta and yellow} colors on a reflective print, we can deduce that a fairly accurate color transformation can be constructed when only {cyan, magenta, yellow} colorants are present on a reflective print. However, since CMYK four-color printing (or even more than five colorants) is prevalent in the commercial printing industry, researchers have shown that the presence of the extra black colorant and all supplemental colorants will noticeably degrade the scanner calibration performance. It is possible to extract the supplemental color channel information and utilize this supplemental information in the scanner calibration and color transformation process that is applied to scanned documents in order to evaluate color information. In this particular embodiment, the scanner calibration method, including an algorithm, includes two portions: a quadratic global regression and neural network based residual approximation. The embodiment the data capture device for this method and algorithm can be a flatbed scanner with an automatic document feeder or a high-speed digital camera.

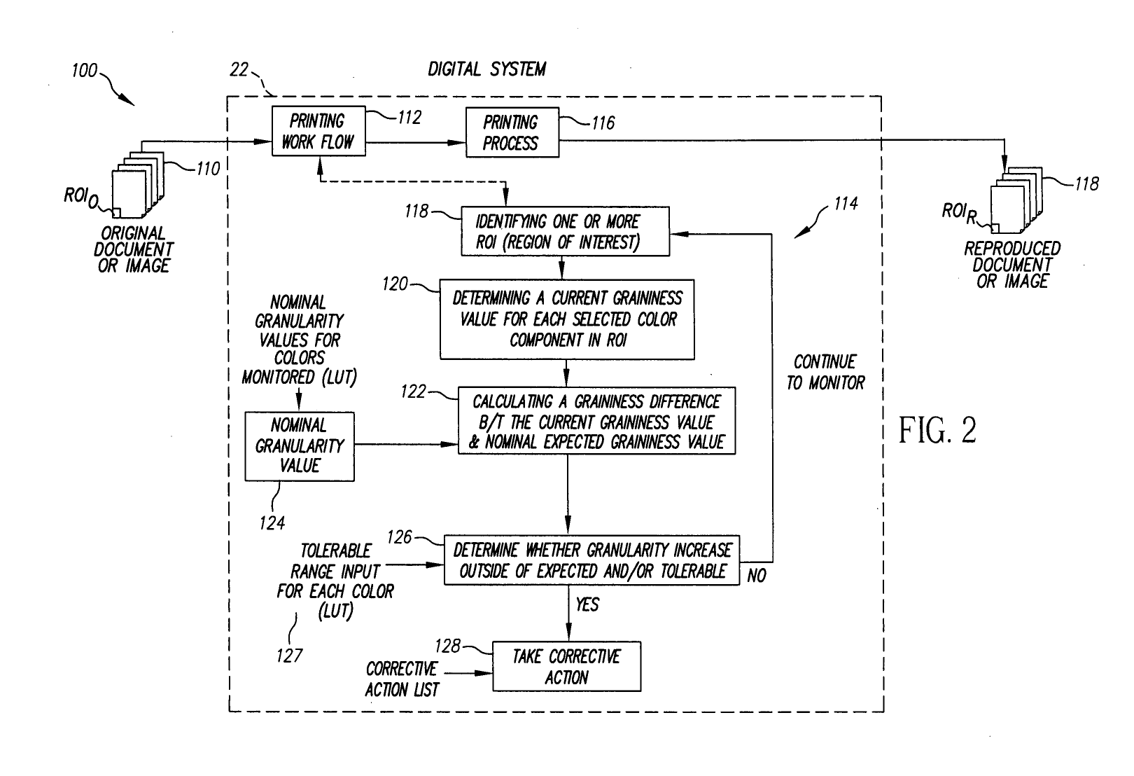

FIG. 2, shows a schematic of an image control method 100 that incorporates a graininess correction. The image control method 100 shown in FIG. 2 could be used in conjunction with the image control system 18 described above. In this method 100, an original document 110, such as in the form of a digitized or scanned file, is first sent to the digital printing system 10. A printing workflow 112 that performs appropriate ICC profile color management functions and other image processing processes and includes the graininess correction is shown that performs the steps shown as part of the total printing workflow process. The ICC profile color management functions are part of an international standard that allows various different input and output color devices such as digital camera, scanner and digital printer to be connected and manages the color profiles such that approximately the same color is represented in each device. In the digital printing system 10, this capability is necessary to accurately render the original document containing various types of input files on a substrate such as paper.

The system, shown here as a digital printing system but which could include other color reproduction systems such as color monitors or cell phone and camera monitors, includes an image control method 114 that begins by calibrating the color reproduction device, in this case in conjunction with a printing process 116, with high-accuracy using a graininess metric including the steps of identifying one or more ROIs (regions of interest) 118. Then determining a current graininess value for each selected color component in the ROI 120, and calculating a graininess difference between the current graininess value and a nominal expected graininess value 122 based on nominal granularity value(s) 124 that are from a LUT or other sources as will be discussed below in more detail. Then determining when the calculated graininess difference falls outside an expected range 126 based on a tolerable or expected range 127 and taking corrective action 128 based on a corrective list or similar information. Although the invention is being described as part of a printing process, it would be understood by those skilled in the art that this system and the corrective method could be applied to any color reproduction device and that the document represents other types of images, such as a color monitor or screen in a camera or cell phone for example.

Since the corrective action is for image enhancement, this method can be applied in the spatial, frequency, or spatial-frequency domains in conjunction with or without image enhancement filters. The objective is to create an accurate translation process between the image-capturing device 14 and the colorimetric measurement device 16 because the colorimetric measurement device closely relates to human visual response while a digital capturing device might not. It is important that the image-capturing device 14 and the colorimetric measurement device 16 are measuring the same location to achieve a valid and accurate translation process.

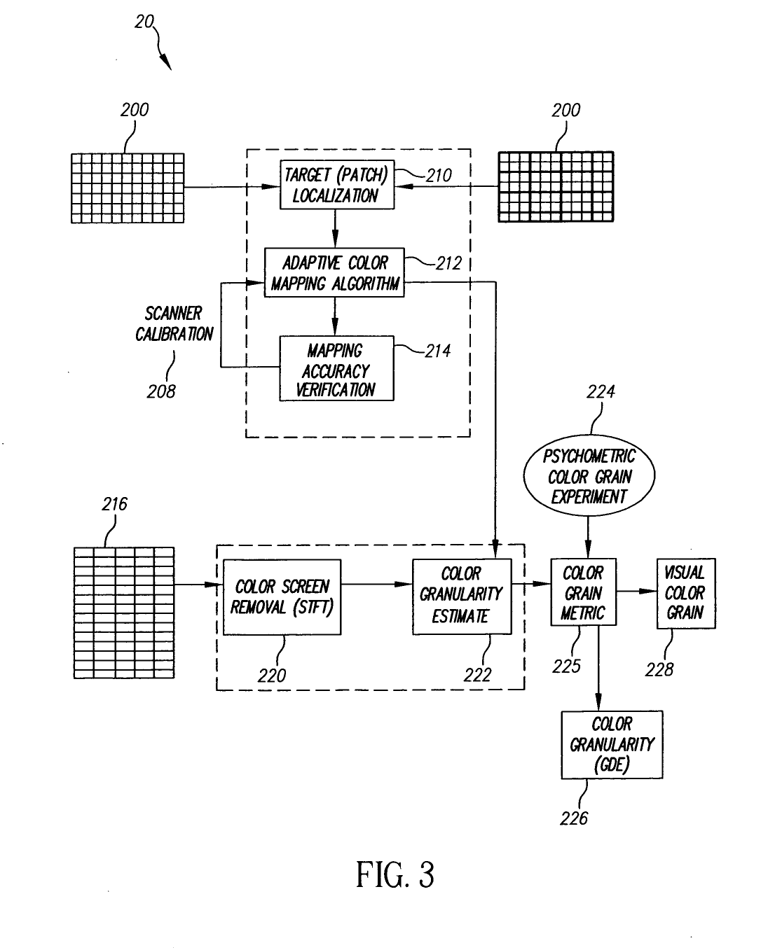

The scanner 14, such as a flatbed scanner is adopted for its capability to capture a wide frequency response range. Color calibration is conducted with respect to every set of colorants on printed samples (4c and 5c) to reduce possible metamerism error with calibration method discussed in ‘Perceptual Color Graininess of Printed Pages via flatbed Scanner, by Yee S. Ng, Chunghui Kuo and Di Lai in the Final Programs and Proceedings, ICIS '06 International Congress of Imaging Science, pp. 122-125’. As shown in FIG. 3, a IT8/7.3 (928 patches) test chart with 4-color printing system and a TCMC5 (1218 patches) test chart with 5-color printing systems (Red, green and blue as a 5th colorant were used in addition to C,M,Y,K for printing this chart) were printed (with color management off) as scanner calibration test charts 200. In the scanner calibration step 208, the following procedures are used: (1) Target (Patch) Localization algorithm 210, which automatically locates the center of color, patches on selected targets. (2) Progressive, adaptive color mapping algorithm 212 with global and local color mapping parameters estimation to achieve high accuracy and smooth mapping function in the mapping accuracy validation step 214 (3) before applying a Cross-Validation approach to reach the optimal generalization performance. One obtains a transformation that translates the RGB flatbed scanner measurement of a particular colorant set for the printing system to the colorimetric (L*a*b*) space. Now the scanner system can be used to measure process control patches and real images and translate the RBG scanner data into the colorimetric (L*a*b*) space.

A color grain metric, also referred to as a graininess metric, can then be built to link the objective color granularity measurement using the flatbed scanner to subjective graininess value as discussed in the Ng ICIS '06 paper. It is also possible to create the graininess metric using other area sensors including use of one of an in-line scanner with linear sensors, flatbed scanner, and camera, such as a 2-D camera. As shown in FIG. 3, test chart 216 consists of (1) 28 patches of various C,M,Y,K colorant combinations of (30, 50, 70 and 100% dot), and (2) 17 patches of simulated popular colors in colorimetric (L*,a*,b*) space is scanned by the flatbed scanner. The color screen signal, Is(x,y|R,G,B) on the scanned image, is first de-screened based on Short-Time Fourier Transform (STFT) 220. The color screen removal process using STFT has been outlined in ‘Chunghui Kuo and Yee S. Ng, Image Graininess via flatbed scanner and image segmentation, Proc. IS&T's NIP21:2005 International Conference on Digital Printing Technologies, pp 84-88’.

The de-screened images (patches) are transformed into the L*a*b* color space via the RGB→L*a*b* transformation process outlined in the scanner calibration process mentioned above. Then the de-screened images (in L*a*b* space) are used to obtain a color granularity estimate 222 (based on CIEDE2000 color difference space) and a psychophysical experiment is done to correlate with subjective color graininess. The color granularity estimate 222 can be obtained in other ways such as with the use of accumulated data as will be discussed below. For the color granularity estimate 222, a sampling area of 12.72 mm² and sampling block size of 1.27 mm×1.27 mm according to ISO13660 Standard is used for granularity (represented in color variation in the CIEDE2000 color difference space as discussed in the Kuo NIP21 paper) measurement. Let σᵢ represents the standard deviation in color (in L*a*b* space) of each block, we can derive the color granularity

$${G}_{Δ E} = \sqrt{{\sum }_{i = 1}^{n} {σ}_{i}^{2} / n}$$

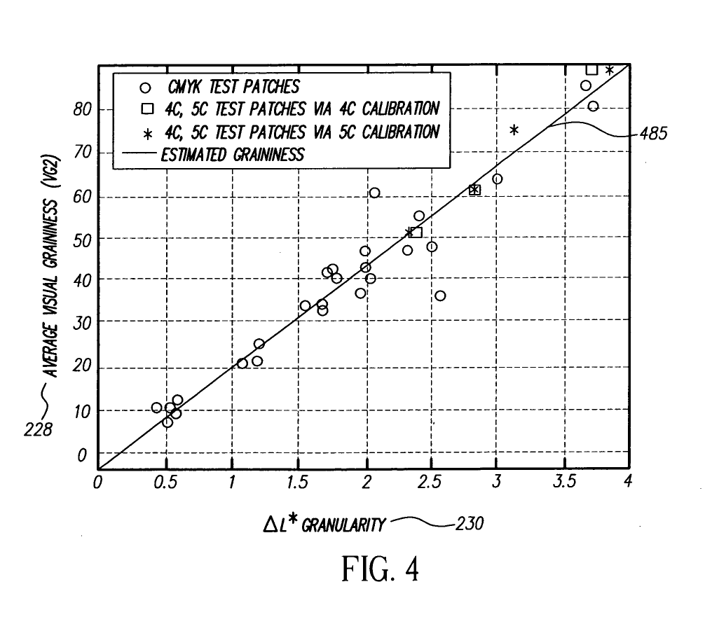

of the sampled area. After the psychometric color grain experiment one can build a color grain metric 225 that links the color granularity G_{ΔE} 226 to color visual grain, VG_{c} 228, so that the visual importance of graininess can be linked to the granularity measurement. In the case of the Ng ICIS '06 paper, for example, one finds that VG_{c} can be reasonably represented by the granularity G_{L} due to L* variation 230 alone (namely σᵢ from L* variation alone) with the following equation, and as shown in FIG. 4.

VG_{c}=23.16×G_{L}−3.6

Therefore, if color process control patches can be used in conjunction with a calibrated flatbed scanner or an in-line scanner for the printer, graininess (visually important) feedback can be obtained for the printing process, and corrective action can be taken when process graininess changes over time.

If the ROI (region of interest) identification can be made by customers (for areas of images that are of significance to the customer) on actual images (say viewable via a monitor), region growing method (with constraints, such as color difference of within 9 ΔE from the position that customer is pointing at, should be included) can be used to acquire color variation data in real-time printing from actual customer images (not test patches which are inefficient). Graininess reading can be obtained, monitored and feedback for control. Region growing method has been described in Kuo's NIP21 paper. The image control system can further incorporating pre-selected colors, such as skin-tone and blue sky, in actual customer images to automatically determine the ROI.

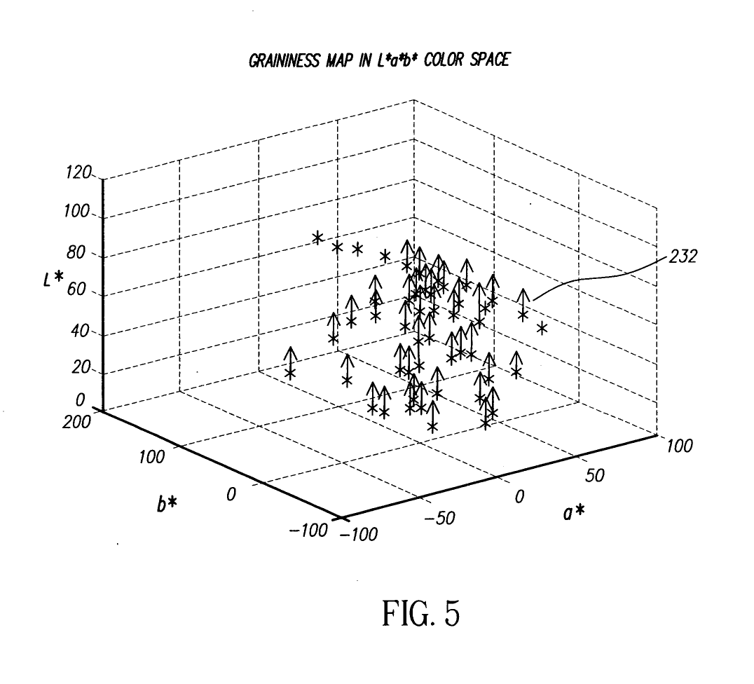

Graininess of the printing process for the printer color gamut can be characterized by printing out test patches (based on a combination of C,M,Y,K coverage combinations) covering regions of the color gamut. Then color granularity can be measured via the calibrated scanner (as discussed above), and the normal color graininess of the printing system including processes such as screening, toning, transfer and fusing are characterized using the graininess/granularity metric. A color graininess map for a 4-color printing process (plotted in the L*, a*, b* color space) is shown in FIG. 5 that can represent “knowledge” of the printer or paper or other relevant to the quality results achievable by the present invention.

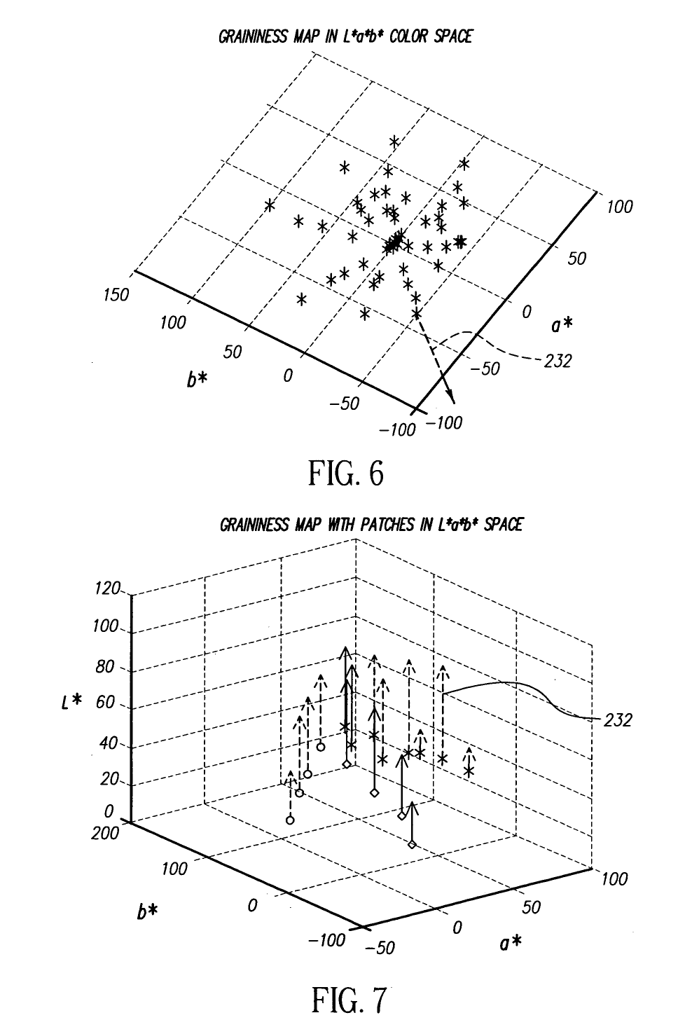

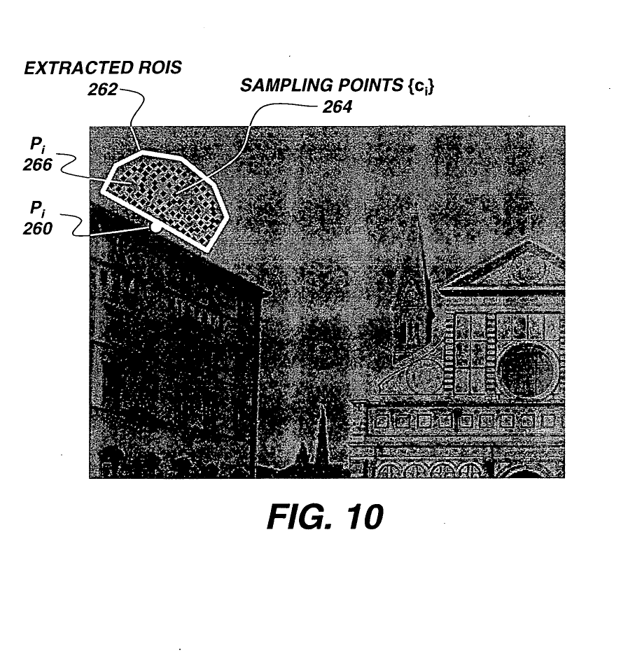

The * marks in FIG. 5 mark the L*a*b* color value of the patches measured, and the length of the arrow represents the graininess value 232, such as graininess magnitude, of the visual graininess of the patch. FIG. 5 shows a typical graininess map that represents the graininess performance of the printing process over the color gamut. FIG. 6 shows a two dimension projection of the location of the patches onto a*b* space which is also discussed further in conjunction to FIG. 10.

To simplify the discussion, let's look at the graininess map for a few process control patches (30%, 50%, 70% and 100% dot) in FIG. 7. FIG. 7 shows process control patches of various colorant % coverage for yellow (color patch location in L*a*b* space marked by a □), cyan (color patch location in L*a*b* space marked by a O), blue (color patch location in L*a*b* space marked by a ⋄) magenta (color patch location in L*a*b* space marked by a *) and red (color patch location in L*a*b* spaced marked by an x). The length of the arrow signifies the visual grain of the color patch. For example, as one might notice, the color graininess of yellow patch is quite small, but that of magenta and cyan are larger.

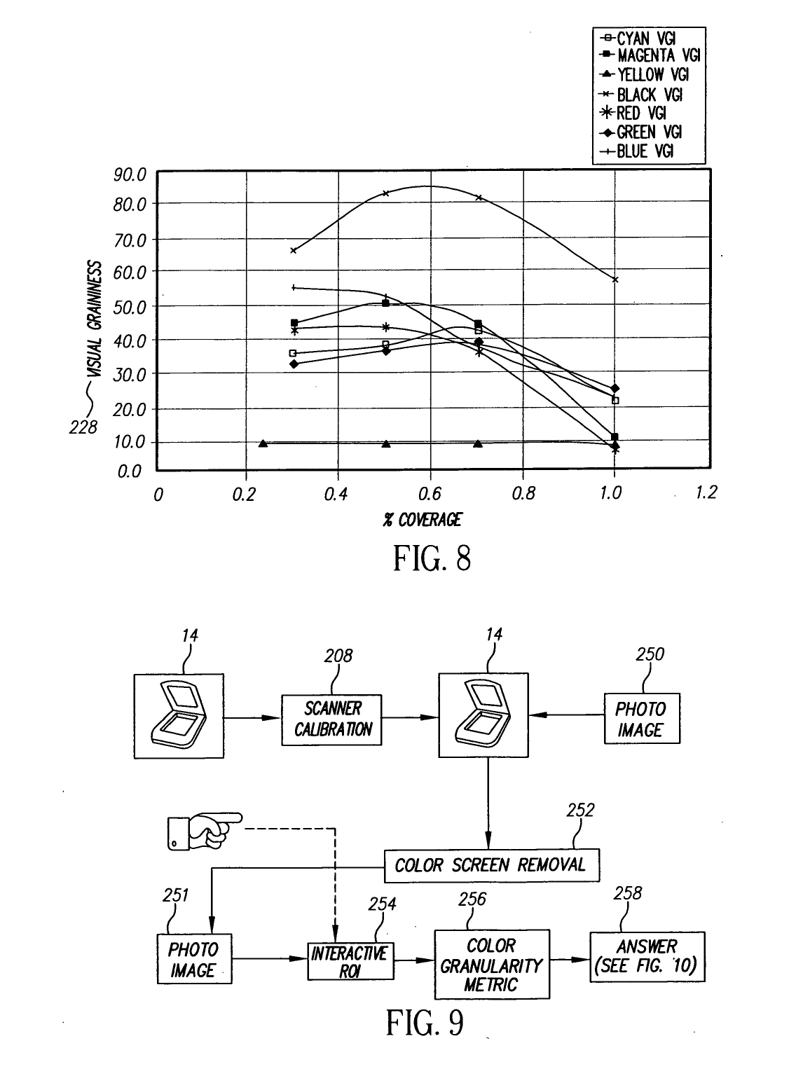

FIG. 8 shows the visual graininess, VG_{c} 228, vs colorant % coverage for some of these process control patches. For the process control patches that involve two color separations, equal primary color separation coverage is assumed for the figure. As one can also see, graininess usually is higher at the mid-tone and lower at higher coverage. The visual graininess, VG_{c} 228, value from the process control chart in FIG. 8 gives the nominal graininess value for the system. There can be a separate nominal graininess for each printer, color component, screen or other input parameters and factors that could affect the output, including the quality of the print. If the system transfer capability is affected negatively (toner/developer aging, sensitivity to environment such as humidity), graininess can increase in the process control patches as well as in customer pictures. So if process control patches are occasionally printed in the system, either on-line or offline calibrated scanner can be used, then granularity can be measured, and visual graininess (of human importance) can be monitored and corrective action taken to fix the problem (such as toner/developer change of a particular color, cleaning of the transfer intermediate roller etc.) if graininess increases beyond the normal (from previous graininess map).

However, using prints from process control patches can also mean waste for the system. Given the scanner's capability to acquire color information at high resolution, one can actually acquire calibrated color information (therefore the color variation information that shows up as color granularity) from customer prints 250. For example, one has shown before that with segmentation and region growing methods (Kuo NIP21 paper), if we have asked for operator input as to the color region to monitor as shown in the process in FIG. 9. Basically an actual customer picture 251, after color screen removal 252, post scanning with the calibrated scanner, that the customer/operator can point to a position of interest interactively and a region of interest (ROI) 254 with a certain color limit criteria (such as color within 9 delta E of the position that the operator points to) is created and color granularity 256 can be obtained resulting in a picture or print 258 as further discussed below in conjunction with FIG. 10. Typically operator may select an extended region with gradual color change that graininess is deemed important from an observer viewpoint.

Graininess can be a subjective response, but granularity is an objective measurement. Granularity can use a fixed LUT with or without the graininess conversion discussed below. The difference is that granularity does not put importance on the visual sensitivity to grain based on color, but graininess does. In many cases the correction for granularity is sufficient to achieve the desired results, such as when only monitoring a few fixed colors which are already pre-weighted, then granularity measurement will do from a monitoring and control viewpoint. For example, if one is only monitoring cyan, magenta, yellow etc on process control patches, then granularity measurement will be sufficient even for specific color such as a certain skin tone. Graininess can be useful when used as a diagnostic since colors can have different importance, such as when yellow is less important than magenta which would require paying attention to the magenta color performance first when it comes to corrective action for graininess. Graininess evens the field, so if a certain visual grain is above a threshold, fix it. Granularity will need a different threshold for different colors.

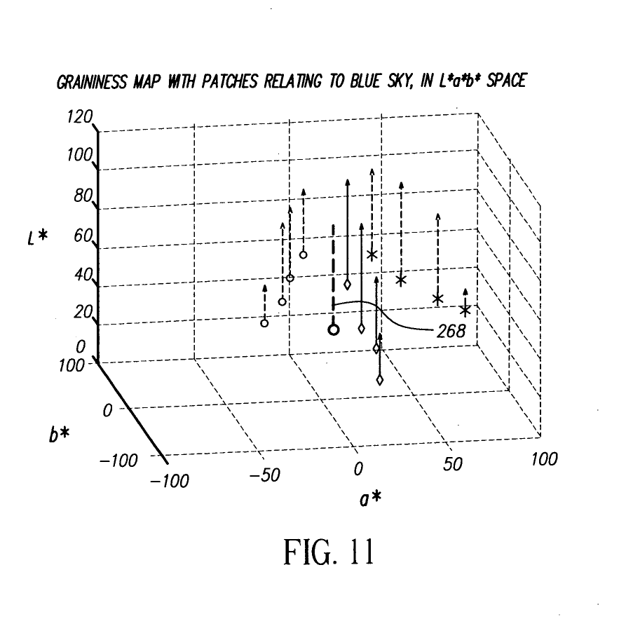

FIG. 10 shows the operator-selected point (Pᵢ) 260, the extracted ROI 262 with a 9 deltaE limit around the color of Pᵢ, 260 and the sampling points (Cᵢ) 264 for the granularity calculation. For example, if the blue sky point (Pᵢ) 266 is supposed to have L*a*b* values of (48.2, 1.76 and −39.7), which are the input for the graininess map shown in FIG. 5, in a certain selected UCR color management color profile, one has a color separation values of ˜(cyan=69%, magenta=43%, yellow=1% and black=2%). The estimated nominal graininess value of the blue sky information from the graininess map, as shown in FIG. 5, is ˜51.7 (268) as shown in FIG. 11.

The length of bolder line in FIG. 11 represents the magnitude of the blue sky graininess and the bold (+) marks the color location of the blue sky point (Pᵢ) in the L*a*b* color space. We also show the graininess expectation of the (30, 50, 70 and 100) %-dot patches for the majority color separations that compose the blue sky color {cyan (marked by a O), magenta (marked by a *)} and relevant overprint such as blue (marked by a ⋄) if they were also printed in this case. So the graininess of the operator marked blue sky can be marked for graininess monitoring.

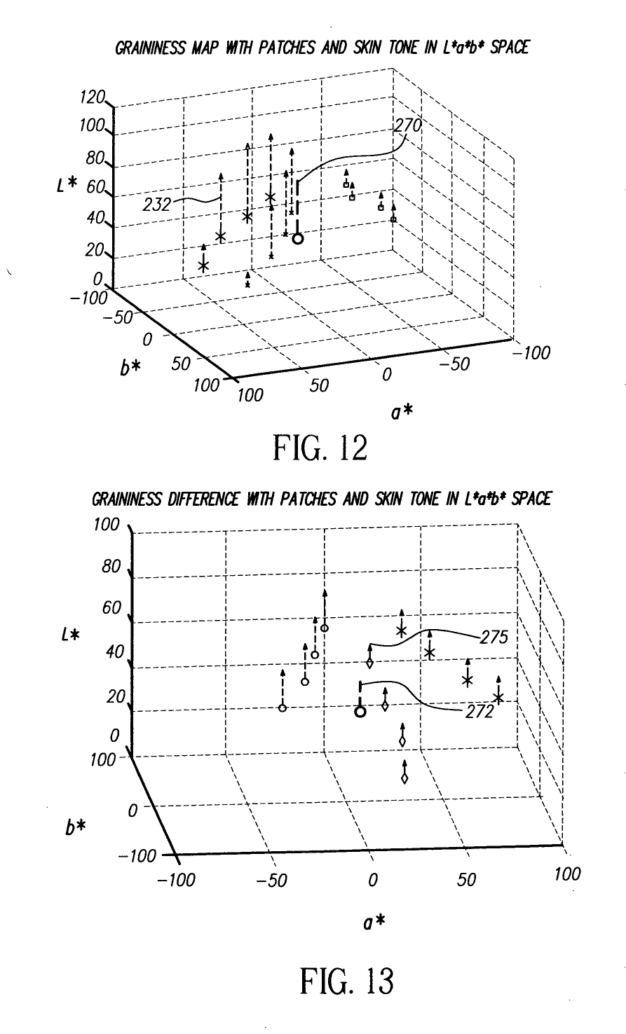

Similar methodology can be applied for other popular colors such as skin tone. For example if operator select a picture location (Pⱼ) with extended region of Caucasian skin tone of ˜L*a*b* values of (L*=64, a* of 27 and b* of 38), the equivalent color separations % coverage after color mapping in one implementation is {cyan=3%, magenta=46%, yellow=63%, black=7%}, namely the predominant separation is magenta and yellow. One can monitor the sky tone graininess with this method. FIG. 12 shows the graininess of this skin tone (red line marked by a •) nominal visual graininess value of ˜41 (270)) and the nominal graininess of the process control steps for its predominant color separations (magenta {marked by a *}, yellow {marked by a □) and overprints (red {marked by a x) if they have been printed at the same time.

Now, if we are monitoring the blue sky and skin tone, and if there is a graininess increase of blue sky, but not skin tone, due to printing process problem (eg., caused by the cyan transfer alone), the graininess difference 272 of the blue sky (˜15.4) from the nominal graininess value can be tracked as shown in FIG. 13 and be traced back to the potential problem in the color separations. In FIG. 13, we have charted the graininess difference (represented by the bold line ended in a +, that marks the color location of Pᵢ) in L*a*b* space. The magnitude of the graininess difference (between the current state of printing and the nominal reference) is represented by the length of the bold line. The expected impact on the graininess of the dominant cyan (marked by a O) separation control chart (if printed at the same time) is also shown. Since if the skin tone graininess does not change, there is little impact from the magenta separation (the blue sky is predominantly cyan and magenta, and the skin tone is predominantly magenta and yellow). Therefore, if the graininess monitoring discloses an increase in graininess in blue sky, but not skin tone, then one should make corrective action to the cyan-printing module if the graininess difference exceeds a tolerable or expected range (275) as shown in FIG. 2.

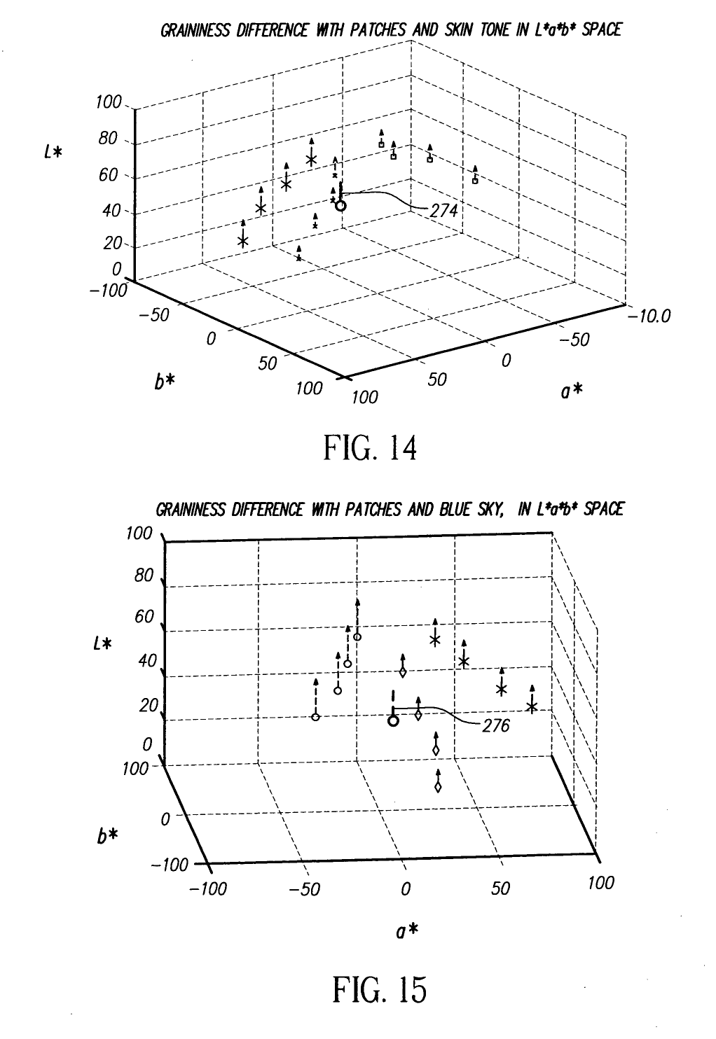

On the other hand, if the graininess increase of the blue sky is coming from the magenta transfer, then the skin tone graininess will be affected as well as shown in FIG. 14. In FIG. 14, one shows the graininess increase (˜12.3) 274 of the skin tone (color position marked by the O, magnitude of the increase represented by the length of the bold line). The corresponding graininess increase of magenta (color separation patches of various coverage are marked by *) and red overprint (overprint patches of various coverage marked by x) if they were printed, are also shown. Also the corresponding increase in the blue-sky graininess is shown in FIG. 15. In FIG. 15, the blue sky graininess increase (˜15) (276) can be expected from the nominal graininess if the problem comes from magenta separation transfer problem of similar magnitude as the one that causes increase in skin tone graininess (in FIG. 14). Therefore by looking at the blue sky and skin tone graininess deviation from their nominal, one can reach the conclusion that the magenta-printing module requires corrective action (in this case, both the blue sky and skin tone graininess are affected if they exceed a reported range). Of course, if the increase in graininess problem is caused by both the magenta and cyan printing modules, then one can still use the graininess increase information and their relative ratios from monitoring of graininess of skin tone and blue-sky areas marked by operators to monitor.

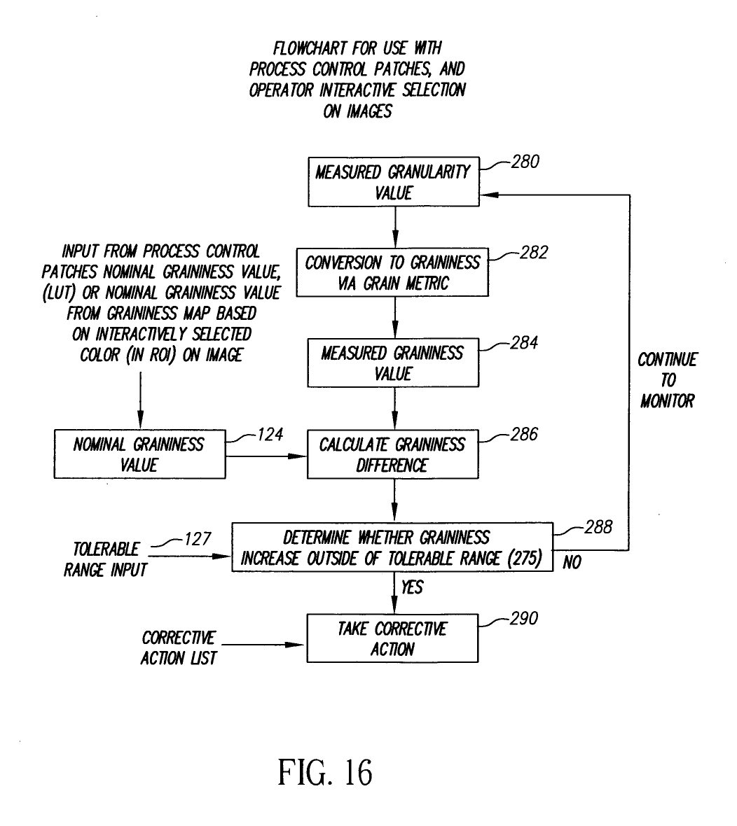

FIG. 16 shows a flow chart that illustrates one embodiment of an image control method for calibrating a color reproduction device using a graininess metric. The flow chart indicated an embodiment for use with process control patches and operator interactive selections on images or documents. The flow chart represents the process steps that start with measuring a granularity value 280, such as those discussed above, converting granularity to a graininess value via a grain metric 282, taking the measured graininess value 284 and comparing it to a nominal graininess value that is determined from input from process control patches nominal graininess values that can be obtained from a lookup table (LUT) or nominal graininess values from graininess maps based on interactively selected color in a range region of interest (ROI) on an image or document. The difference between the measured graininess value and the nominal graininess value which is calculated 286 to determine whether graininess has increased outside a tolerable or expected range 288 obtained from input such as from customer or predetermined values. If the differences are outside the ranges then corrective actions are taken 290 based on a corrective action list but if the difference is within the color for expected range and then the system continues to monitor the region of interest.

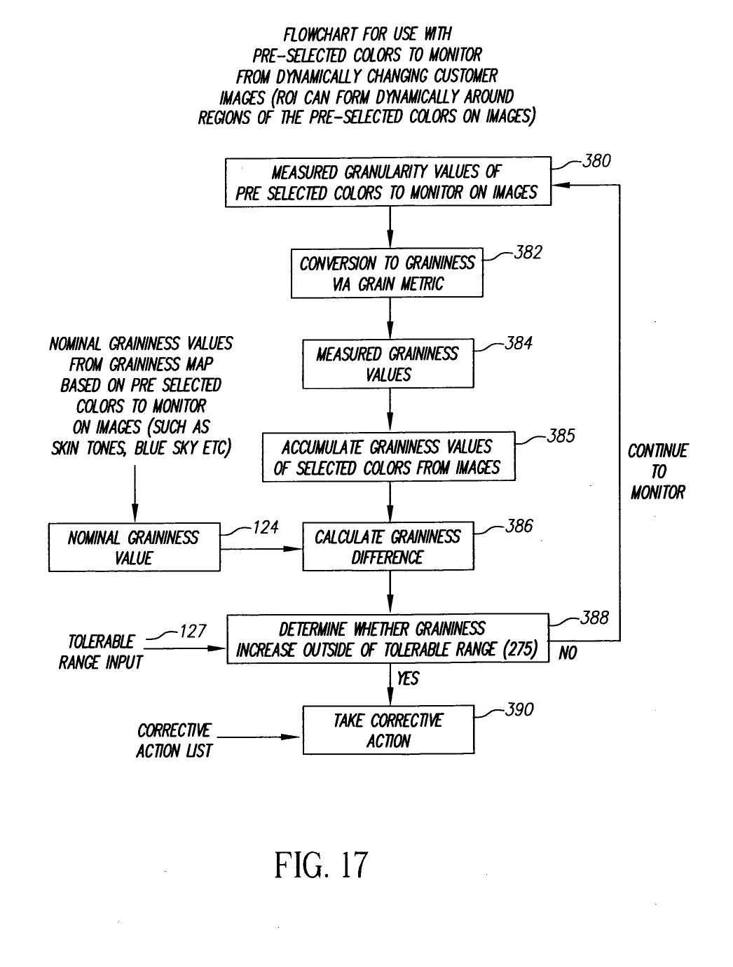

FIG. 17 shows a flow chart that illustrates one embodiment of an image control method for calibrating a color reproduction device using a graininess metric. The flow chart indicates an embodiment for use with pre-selected colors to monitor from dynamically changing customer images or documents (ROI can be determined dynamically around regions of pre-selected colors on those images). The flow chart represents the process steps that start with measuring a granularity value 380 for pre-selected colors to monitor on the image or document, such as those discussed above, converting granularity to a graininess value via a grain metric 382, taking the measured graininess value 384 and comparing it to a nominal graininess value that is determined from input from graininess map based on pre-selected colors to monitor on mages (such as skin tones, blue sky, etc.) The graininess values of selected colors from these images are accumulated 385 and a difference between the measured graininess value and the nominal graininess value is calculated 386 to determine whether graininess is increased outside a tolerable or expected range 388 obtained from input such as from customer or predetermined values. If the differences are outside the range then corrective actions are taken 390 based on a corrective action list but if the difference is within the expected range for the color for expected range and then the system continues to monitor the region of interest.

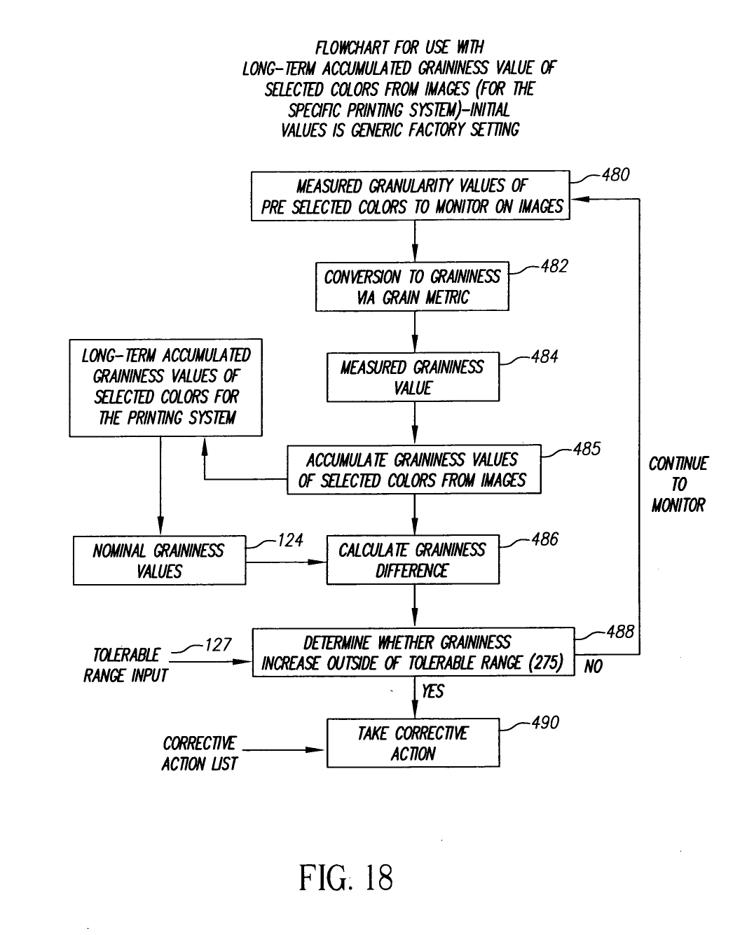

FIG. 18 shows a flow chart that illustrates one embodiment of an image control method for calibrating a color reproduction device using a graininess metric. The flow chart indicated an embodiment for use with long-term accumulated graininess values for selected colors from the supplied images or documents (for a specific printing system or other critical components of the process) where the initial values are given, such as in set generic “set values.” The flow chart represents the process steps that start with measuring a granularity value 480 for pre-selected colors to monitor on the image or document, such as those discussed above, converting granularity to a graininess value via a grain metric 482, taking the measured graininess value 484 and comparing it to a nominal graininess value that is determined from accumulated l (long-term) graininess values of selected colors for that particular printing system or other parameter such as color, screen etc. The graininess values of selected colors from these images are accumulated 485 and fed to the long term accumulation for nominal values and a difference between the measured graininess value and the nominal graininess value is calculated 486 to determine whether graininess is increased outside a tolerable or expected range 488 obtained from input such as from customer or predetermined values. If the differences outside the range than corrective actions are taken 490 based on a corrective action list but if the difference is within the color for expected range and then the system continues to monitor the region of interest.

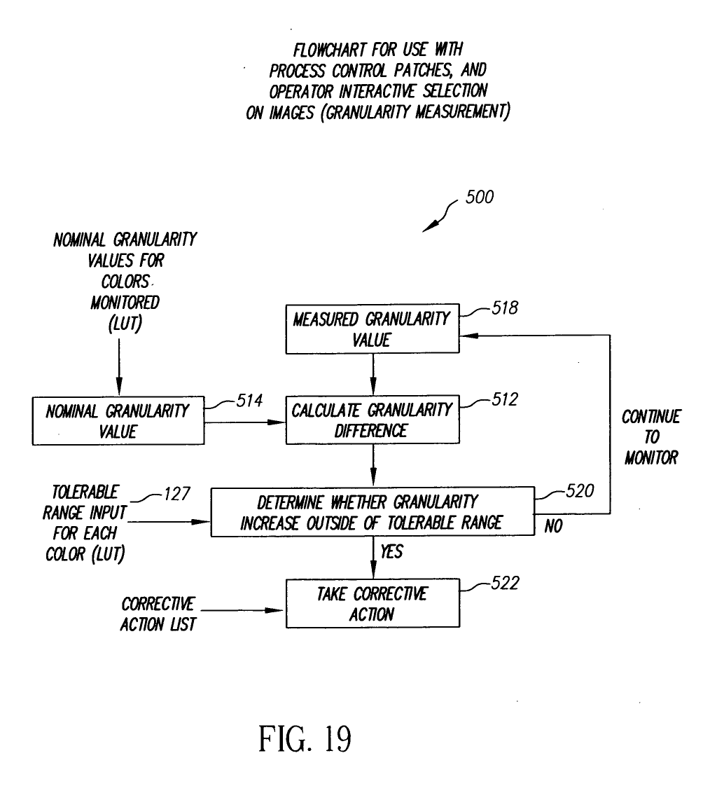

FIG. 19 shows a flow chart that illustrates one embodiment of an image control method 500 for calibrating a color reproduction device using a granularity metric. The flow chart including the steps of measuring granularity value 510, which could be a value for each selected color component in an ROI, and calculating a granularity difference 512 between the current measured granularity value and a nominal granularity value based on nominal granularity value(s) 514 that are from a LUT or other sources. Then determining when the calculated graininess difference falls outside an expected range 520 based on a tolerable or expected range 488 and taking appropriate corrective action 522 based on a corrective list or similar information. Although the invention is being described as part of a printing process, it would be understood by those skilled in the art that this system and the corrective method could be applied to any color reproduction device and that the document represents other types of images, such a color monitor or screen in a camera or cell phone for example.

The interactive way of monitoring specific areas of interest by operator can be further extended into automatic monitoring. Since some of the most important memory color region of significant interest in graininess is known (for example the blue sky and skin tone area mentioned above). One can extend the monitoring concept to include colors of blue-sky tone of various types (blue sky with desert, blue sky with snow, blue sky with grass) and lightness, skin tones of various shades (Caucasian, Asian, Indian, African, etc). So one can acquire in-line (via calibrated scanner) graininess information of extended regions (size) of color within a certain limit of the monitoring colors from real prints. So even if the prints are changing, the accumulative information of graininess of the monitored colors can be used for new process baseline, diagnostic and corrective action purpose without printing wasteful process control patches.

Automating the image control system includes both accumulating graininess data over time so that it can be used by the system and/or operator and customer to determine what corrections should be made. This could be done by modifying the reset nominal values or changing the other criteria that effect print quality. It is suitable for variable images, versus the customer marked ROI or process controlled patches (both are fixed images). This automatic control system could also include separately or in combination with the automatic accumulation of graininess data, the automatic determination of ROI, such as incorporating pre-selected colors, such as skin-tone and blue sky, in actual customer images to automatically determine the ROI. The assigned colors are used to monitor and each color has a nominal value. Which can be represented in a LUT or other means. The system can accumulate data to adjust this nominal value or to compare to operating conditions and other input parameters as discussed above in conjunction to FIGS. 17 and 18.

When used in correcting graininess or in granularity tracking in conjunction with corrective action or ROI determination, as accumulation data, the objective measurement can often be all that is needed as far as a corrective action to achieve the desired results. This is especially valuable if somebody does not plan to go across colors. For example if one is only monitoring cyan, magenta, yellow etc on process control patches, then granularity measurement will do. Even for specific color such as a certain skin tone. Graininess is useful when we go across colors in a diagnostic, such as yellow is less important than magenta, for example, so when it comes to corrective action, one has be a lot bigger in granularity in yellow before the fix needs to be done compased to magenta. Graininess evens the field, so if a certain visual grain is above a threshold, fix it. Granularity will need different thresholds for different colors.

The preselected colors (such as memory colors of importance, skin-tone, blue sky and such) to monitor and accumulate from real images. The difference between customer selected ROI and process control patches to this mode is that in the preselected color monitoring case, the images are variable, while process control patches and customer selected ROIs are fixed images.

The invention has been described in detail with particular reference to certain preferred embodiments thereof, but it will be understood that variations and modifications can be effected within the spirit and scope of the invention.

1. An image control method for calibrating a color reproduction device using a graininess metric comprising the steps of:
a. identifying one or more ROI (region of interest);
b. determining a current graininess value for each selected color component in the ROI;
c. calculating a graininess difference between the current graininess value and a nominal expected graininess value;
d. determining when the calculated graininess difference falls outside an expected range; and
e. taking corrective action.

2. The image control method of claim 1, the relating step further comprising creating the graininess metric using an area sensor comprising one of an in-line scanner, flatbed scanner, and camera.

3. The image control method of claim 1, the identifying step automatically determines the ROI.

4. The image control method of claim 3, wherein an interactive step of identifying the ROI comprises combining captured measurements from one or more ROI on one or more documents.

5. The image control method of claim 3, wherein the automatic step of identifying the ROI comprises combining captured measurements from one or more ROI on one or more documents.

6. The image control method of claim 1, the calculating step further comprising combining captured measurements from one or more ROI and the corresponding color separation contribution and the corresponding nominal values to determine what corrective action is recommended.

7. The image control method of claim 6, the calculating step further comprising identifying the color component that is contributing to the calculated graininess difference that falls outside the expected range.

8. The image control method of claim 1, further comprising a transmitting step for transmitting some or all of the graininess value related information to one or more of a remote proofing devices, including calibrated monitors (soft proof) and proof printers (hard proof), for quality assurance use by remote users.

9. The image control method of claim 1, further comprising a transmitting step for transmitting some or all of the graininess value related information back to the color reproduction device.

10. The image control method of claim 1, further comprising determining the nominal expected graininess value from one or more of the following: a graininess map, a collection of color patches printed with standard CMYK colorants from the document, a look up table (LUT), preinstalled as a preset value in the color reproduction device or accumulated from collected data from the color reproduction device.

11. The image control method of claim 1, further comprising using patches and/or printed images as the source of graininess nominal values.

12. The image control method of claim 1, further pre-selecting colors, such as skin-tone and blue sky, in actual customer images to automatically determine the ROI.

13. The image control method of claim 1, wherein the determining step further comprises accumulating graininess and/or granularity data over time.

14. The image control method of claim 13, further comprising incorporating a diagnostic where one color is preferred over another, such as yellow is less important than magenta, when it comes to corrective action.

15. An image control system using a color reproduction device for calibrating a color reproduction device using a graininess metric, the system comprising:
a print engine to print a digital image on a substrate, said printing being performed in accordance with initial printing settings comprising one or more nominal expected graininess values;
an image capture system adapted to capture a digital image of a document and to generate captured image data reflecting an appearance of the image in one or more ROIs (regions of interest) comprising one or more graininess values;
a processor adapted to determine corrective action when the calculated graininess difference falls outside an expected range, the processor further comprising:
a measurement device to measure the current graininess value for each selected color component at the identified ROI positions to create measured graininess magnitude value for each selected color component; and
a comparator to relate the measured graininess values and the nominal expected graininess values to automatically determine a graininess difference between the current graininess value and a nominal expected graininess value.

16. The image control system of claim 15 the processor further comprising creating the graininess metric using an area sensor comprising one of an in-line scanner, flatbed scanner, and camera.

17. The image control system of claim 15, the processor automatically determining the ROI.

18. The image control system of claim 15, the processor accumulating measured graininess values in one or more ROI on one or more documents to calculate cumulative measured graininess values.

19. The image control system of claim 18, the processor further combining the cumulative captured measurements from one or more ROI and the corresponding color separation contribution and the corresponding nominal values to determine what corrective action is recommended.

20. The image control system of claim 15 further comprising a transmitter for transmitting some or all of the graininess value related information to one or more of a remote proofing devices, including calibrated monitors (soft proof) and proof printers (hard proof), for quality assurance use by remote users.

21. The image control system of claim 15 further comprising a transmitter for some or all of the graininess value related information back to the color reproduction device.

22. The image control system of claim 15 further comprising a user interactive device.

23. The image control system of claim 15 further comprising the nominal expected graininess value from one or more of the following: a graininess map, a collection of color patches printed with standard CMYK colorants from the document, a look up table (LUT), preinstalled as a preset value in the color reproduction device or accumulated from collected data from the color reproduction device.

24. The image control system of claim 15 the processor further incorporating the pre-selection of pre-selected colors, such as skin-tone and blue sky, in actual customer images to automatically determine the ROI.

25. The image control system of claim 15, the processor further incorporating graininess data accumulated over time.

26. An image control method for calibrating a color reproduction device using a granularity metric comprising the steps of:
a. identifying one or more ROI (region of interest);
determining a current granularity value for each selected color component in the ROI;
b. calculating a granularity difference between the current granularity value and a nominal expected granularity value;
c. determining when the calculated granularity difference falls outside an expected range; and
d. taking corrective action.

27. The image control method of claim 26, the relating step further comprising creating the granularity metric using an area sensor comprising one of an in-line scanner, flatbed scanner, and camera.

28. The image control method of claim 26, the identifying step automatically determines the ROI.

29. The image control method of claim 28, wherein the automatic step of identifying the ROI comprises combining captured measurements from one or more ROI on one or more documents.

30. The image control method of claim 26, the calculating step further comprising combining captured measurements from one or more ROI and the corresponding color separation contribution and the corresponding nominal values to determine what corrective action is recommended.

31. The image control method of claim 30, the calculating step further comprising identifying the color component that is contributing to the calculated granularity difference that falls outside the expected range.

32. The image control method of claim 26, further comprising a transmitting step for transmitting some or all of the granularity value related information to one or more of a remote proofing devices, including calibrated monitors (soft proof) and proof printers (hard proof), for quality assurance use by remote users.

33. The image control method of claim 26, further comprising a transmitting step for transmitting some or all of the granularity value related information back to the color reproduction device.

34. The image control method of claim 26, further comprising determining the nominal expected granularity value from one or more of the following: a granularity map, a collection of color patches printed with standard CMYK colorants from the document, a look up table (LUT), preinstalled as a preset value in the color reproduction device or accumulated from collected data from the color reproduction device.

35. An image control method for calibrating a color reproduction device with high-accuracy using a graininess metric comprising the steps of:
a. identifying one or more ROI (region of interest);
b. determining a current graininess value for each selected color component in the ROI with a digital printing system;
c. calculating a graininess difference between the current graininess value and a nominal expected graininess value;
d. determining when the calculated graininess difference falls outside an expected range; and
e. taking corrective action.

36. The image control method of claim 35, the relating step further comprising creating the graininess metric using an area sensor comprising one of an in-line scanner, flatbed scanner, and camera.

37. The image control method of claim 35, the identifying step automatically determines the ROI.

38. The image control method of claim 37, wherein the automatic step of identifying the ROI comprises combining captured measurements from one or more ROI on one or more documents [cumulatively].

39. The image control method of claim 35, the calculating step further comprising combining captured measurements from one or more ROI and the corresponding color separation contribution and the corresponding nominal values to determine what corrective action is recommended.

40. The image control method of claim 39, the calculating step further comprising identifying the color component that is contributing to the calculated graininess difference that falls outside the expected range.

41. The image control method of claim 35, further comprising a transmitting step for transmitting some or all of the graininess value related information to one or more of a remote proofing devices, including calibrated monitors (soft proof) and proof printers (hard proof), for quality assurance use by remote users.

42. The image control method of claim 35, further comprising a transmitting step for transmitting some or all of the graininess value related information back to the color reproduction device.

43. The image control method of claim 35, further comprising determining the nominal expected graininess value from one or more of the following: a graininess map, a collection of color patches printed with standard CMYK colorants from the document, a look up table (LUT), preinstalled as a preset value in the color reproduction device or accumulated from collected data from the color reproduction device.

44. The image control method of claim 35, further comprising using patches and/or viewed images that are digitized and to be printed as the source of graininess nominal values.

45. The image control method of claim 35, further pre-selecting colors, such as skin-tone and blue sky, in actual customer images to automatically determine the ROI.

46. The image control method of claim 35, wherein the determining step further comprises accumulating graininess data over time.

47. The image control method of claim 35, wherein the determining step further comprises accumulating granularity data over time.

48. The image control method of claim 47, further comprising incorporating a diagnostic where one color is preferred over another, such as yellow is less important than magenta, when it comes to corrective action.
